(19) United States
(12) Patent Application Publication
(10) Pub. No.: US 2024/0315052 A1
(43) Pub. Date: Sep. 19, 2024

(54) SEMICONDUCTOR STORAGE DEVICE

(71) Applicant: Kioxia Corporation, Tokyo (JP)

(72) Inventor: Daisaburo TAKASHIMA, Yokohama Kanagawa (JP)

(21) Appl. No.: 18/595,323

(22) Filed: Mar. 4, 2024

(30) Foreign Application Priority Data
Mar. 16, 2023 (JP) 2023-041586

(51) Int. Cl. H10B 63/00; H10B 63/10

(52) U.S. Cl. CPC H10B 63/845; H10B 63/10; H10B 63/34

(57) ABSTRACT

A semiconductor storage device includes a stacked body having a plurality of conductive layers stacked in a stacking direction with an insulating layer interposed therebetween, and a columnar structure that extends in the stacking direction in the stacked body. The columnar structure has a variable-resistance film, a semiconductor film, an insulating film, and a resistor film, all of which extend in the stacking direction in the stacked body. The semiconductor film is between the variable-resistance film and the conductive layer. The insulating film is between the semiconductor film and the conductive layer. The resistor film is between the variable-resistance film and the semiconductor film. Memory cells are formed at locations where the conductive layers, the variable-resistance film, and the semiconductor film intersect. In each of the memory cells, the thickness of the resistor film is greater than the thickness of the variable-resistance film.

### CROSS-REFERENCE TO RELATED APPLICATION(S)

This application is based upon and claims the benefit of priority from Japanese Patent Application No. 2023-041586, filed Mar. 16, 2023, the entire contents of which are incorporated herein by reference.

### FIELD

Embodiments described herein relate generally to a semiconductor storage device.

### BACKGROUND

One type of semiconductor storage device includes a variable-resistance film and a semiconductor film extending in a stacking direction in a stacked body in which a plurality of conductive layers are stacked separated from one another. In such a device, a plurality of memory cells are formed at a plurality of intersection positions at which the plurality of conductive layers intersect with the variable-resistance film and the semiconductor film, and it would be desirable to achieve design flexibility.

### DESCRIPTION OF THE DRAWINGS

FIG. 1 is a diagram showing a schematic configuration of a semiconductor storage device according to an embodiment.

FIG. 2 is a circuit diagram showing a configuration of a string in the embodiment.

FIG. 3 is a perspective view showing a configuration of a memory cell array in the embodiment.

FIG. 4 is a cross-sectional view showing the configuration of the memory cell array in the embodiment.

FIGS. 5A-5C depict a cross-sectional view, a plan view, and a circuit diagram of the configuration of the memory cell in the embodiment.

FIGS. 6A-6B are diagrams showing a current path of the memory cell in the embodiment.

FIGS. 7A-7C are diagrams showing a characteristic of a resistor film according to a first modification example of the embodiment.

FIGS. 8A-8C are diagrams showing a current density distribution near a selected memory cell at the time of writing, including one for a second modification example of the embodiment.

FIGS. 9A-9C are diagrams showing a temperature distribution near the selected memory cell at the time of writing, including one for the second modification example of the embodiment.

FIGS. 10A-10D are diagrams showing a temperature distribution of a variable-resistance film at the time of writing, including ones for a third modification example of the embodiment.

FIGS. 11A-11C are diagrams showing voltage drops in a string at the time of writing, including one for a fourth modification example of the embodiment.

FIGS. 12A-12D are diagrams showing a current change between a set state and a reset state of the memory cell at the time of reading, including ones for a fifth modification example of the embodiment.

FIGS. 13A and 13B are diagrams showing a current path of a set state and reset state of the memory cell at the time of reading in the fifth modification example of the embodiment.

FIG. 14 is a cross-sectional view showing a configuration of the memory cell array of a prior device.

FIG. 15A is a graph that shows a voltage change with respect to a Z position of the channel semiconductor film of the prior device.

FIG. 15B is a cross-sectional view that shows a change in a current density distribution with respect to the Z position of the channel semiconductor film of the prior device.

FIG. 16 is a diagram showing an resistance condition for operation of the memory cell in the memory cell array of the prior device.

FIGS. 17A-17C are diagrams showing a characteristic of the variable-resistance film in the memory cell array of the prior device.

FIG. 18 is a diagram showing a current path of a memory cell when the thickness of resistor film is smaller than the thickness of the variable-resistance film in the memory cell array of the prior device.

FIGS. 19A-19D are diagrams showing a temperature distribution of the variable-resistance film at the time of writing in the memory cell array of the prior device.

### DETAILED DESCRIPTION

Embodiments provide a semiconductor storage device that can be flexibly designed.

In general, according to one embodiment, a semiconductor storage device having a stacked body and a columnar structure is provided. In the stacked body, a plurality of conductive layers are stacked in a first direction with an insulating layer interposed therebetween. The columnar structure extends in the stacking direction in the stacked body. The columnar structure has a variable-resistance film, a semiconductor film, an insulating film, and a resistor film. The variable-resistance film extends in the stacking direction in the stacked body. The semiconductor film extends in the stacking direction between the variable-resistance film and the conductive layer. The insulating film extends in the stacking direction between the semiconductor film and the conductive layer. The resistor film extends in the stacking direction between the variable-resistance film and the semiconductor film. A plurality of memory cells are formed at locations where the plurality of conductive layers, the variable-resistance film, and the semiconductor film intersect. In each of the plurality of memory cells, the thickness of the resistor film is greater than the thickness of the variable-resistance film.

A semiconductor storage device according to the embodiments will be described in detail with reference to the accompanying drawings. The present disclosure is not limited by the embodiment.

### EMBODIMENT

In a semiconductor storage device according to the embodiments, a variable-resistance film and a semiconductor film extend in a stacking direction in a stacked body in which a plurality of conductive layers are stacked via an insulating layer, a plurality of memory cells are formed at a plurality of intersection positions where the plurality of conductive layers intersect with the variable-resistance film and the semiconductor film. Efforts will be made to allow for flexible design.

The semiconductor storage device is also referred to as a semiconductor memory. The semiconductor memory is used as a main storage of a large computer and in a personal computer PC, a home appliance, a mobile phone, and the like. As a type of semiconductor memory, volatile Dynamic RAM (DRAM), Static RAM (SRAM), nonvolatile Mask ROM (MROM), Flash EEPROM such as NAND type flash memory and NOR type flash memory are on the market.

The DRAM is a volatile memory, but is excellent in low cost (cell area of DRAM is less than ¼ of cell area of SRAM) and high speed (faster than FlashEEPROM), and has a large market in a PC market and a mobile phone market.

On the other hand, a nonvolatile Flash EEPROM that is rewritable and retains data after being turned off has a very large market for mobile phones, various cards, SSDs, and the like in recent years. In particular, a three-dimensional flash memory has become mainstream in the current market because it has a structure, including control gates (in particular, word lines) that are stacked and memory cells formed in holes that are collectively formed after stacking the control gates, that has made it possible to reduce costs.

However, in the flash memory, the number of times that can be rewritten (W/E times) is limited to only about 10 to the 3rd power to the 10 to the 4th power, the writing time requires a few microseconds to milliseconds, and a high voltage of 12 V to 22 V is required. Therefore, there is room in the art for improvement in terms of miniaturization and performance.

In this respect, in recent years, development of a ferroelectric random access memory (FeRAM), a magnetoresistive random access memory (MRAM), a phase change memory (PCM), a resistive random access memory (ReRAM), and the like have been introduced as a new type of memory. Among these, MRAM, PCM, and ReRAM store data by changing the resistance of the data storage element of the memory cell.

The magnetoresistive random access memory (MRAM) has a problem of a small resistance change rate of about 200% and an antiferromagnetic field, making scaling difficult. However, the phase change memory (PCM) and the resistive random access memory (ReRAM), which are comparable to the NOR-type flash memory and the NAND-type flash memory in terms of its ability to perform multivalued operations, can have a resistance change rate that is much higher than the flash memory, ranging from two digits to five digits Thus, write current and read current required for the operations can be reduced, making it suitable for high integration and reduction in memory element size. These variable-resistance memories such as PCM and ReRAM have a potential to reduce costs than a NAND-type flash memory by three-dimensionally stacking.

As a method of three-dimensionally stacking these type of memory, a columnar structure that extends in a stacking direction in a stacked body is considered. In the stacked body, a plurality of layers of a conductive layer as a word line and an insulating layer are alternately stacked in a direction perpendicular to a substrate. A columnar structure is formed inside the stacked body in which a hole is opened in a direction perpendicular to the substrate. In the columnar structure, an insulating film (a gate insulating film) as a gate, a semiconductor film (a channel semiconductor film) as a channel, a variable-resistance film such as a phase change material, and an insulating film (a core insulating film) as a core are formed by sequentially forming from an outer periphery of the hole opening toward an inner periphery. A plurality of memory cells are formed at a plurality of intersection positions where the plurality of conductive layers, the variable-resistance film, and the semiconductor film intersect with each other. A plurality of memory cells are connected in a chain shape to form a chain-type three-dimensional structure (a structure in which a plurality of memory cells including transistors and phase change materials that are electrically connected in parallel, are electrically connected in series).

As the operation, a cell transistor of a selected memory cell is turned off, and a cell transistor of a non-selected memory cell is turned on. When a memory cell of a word line WL2 is selected, transistors corresponding to a string selection signal SG and word lines excluding the word line WL2 (i.e., non-selected word lines WL0 to WL1 and WL3 to WLn, wherein n is two or more) are turned on, and a transistor corresponding to the selected word line WL2 is turned off. A source line SL is set to 0 V and a bit line BL is set to High, and a voltage is applied to the string.

When the resistance of the variable-resistance film is sufficiently larger than the on-resistance of the channel semiconductor film, in the non-selected memory cell, a current flows through the channel semiconductor film of the transistor that is turned on, and in the transistor in the selected memory cell that is off, a current does not flow through the channel semiconductor film and instead the current flows through the variable-resistance film.

Therefore, in the write operation, a current and a voltage can be applied to the variable-resistance film of any memory cell of the string, the variable-resistance film generates heat, and the temperature can be increased. Accordingly, a resistance value of the variable-resistance film can transition from high resistance to low resistance (which is referred to as a set operation) or from low resistance to high resistance (which is referred to as a reset operation).

In the read operation, a voltage is similarly applied between the bit line BL and the source line SL, and the resistance value of the variable-resistance film of the selected memory cell can be read.

However, when the resistance of the variable-resistance film of the selected memory cell is substantially equal to the on-resistance of the channel semiconductor film, a current also flows through the variable-resistance film of the non-selected memory cell, and there is a possibility that heat is generated and an erroneous operation is performed.

When the resistance of the variable-resistance film of the selected memory cell is lower than the on-resistance of the channel semiconductor film, because the divided voltage of the voltage applied between the bit line BL and the source line SL, which is applied to the variable-resistance film of selected memory cell, may not be sufficient, there is a possibility that sufficient heat is not generated and the operation cannot be performed.

That is, in a semiconductor storage device such as a phase change memory having a chain-type three-dimensional structure, it may be required to have the resistance of a variable-resistance film, such as a phase change material, to be sufficiently larger than the on-resistance of the channel semiconductor film. This poses a design problem because the atomic material and the composition of the variable-resistance film, such as the phase change material, that can be used are limited.

In order to solve the above problems, in the semiconductor storage device, the following configurations (1) to (7) may be adopted in part or entirely.

(1) In a semiconductor storage device, a columnar structure extends in a stacking direction in a stacked body. In the stacked body, a plurality of word lines and an insulating layer are alternately stacked in a plurality of layers in a vertical direction of the substrate. The columnar structure is formed inside the stacked body in which a hole is opened in a direction perpendicular to the substrate. In the columnar structure, a gate insulating film, a channel semiconductor film, a resistor film, a variable-resistance film, and a core insulating film are formed by sequentially forming them in order from the outer periphery toward the center. The plurality of memory cells are formed at the plurality of intersection positions where the plurality of conductive layers, the variable-resistance film, and the channel semiconductor film intersect with each other. In each memory cell, the thickness of the resistor film is greater than the thickness of the variable-resistance film.

(2) In the configuration (1), the variable-resistance film may be formed of a phase change material, and the resistor film may be formed of a high-resistance material that does not undergo a phase change.

(3) In the configuration (2), the resistor film may further contain a Ge atom and one or more elements selected from the group consisting of P, As, Sb, and Bi as an impurity added thereto.

(4) In the configuration (2), the electrical conductivity of the resistor film may be 4 S/cm or more and 40 S/cm or less.

(5) In the configuration (2), a voltage applied to the conductive layer corresponding to a selected memory cell among the plurality of memory cells is lower than the voltage applied to the conductive layer corresponding to a non-selected memory cell.

(6) In the configuration (2), a thickness of the semiconductor film in a portion in contact with the conductive layer is smaller than a thickness of the semiconductor film in a portion in contact with the insulating layer.

(7) In the configuration (1), a thickness of the resistor film may be 10 nm or more.

According to the semiconductor storage device in which the configurations (1) to (7) can be adopted, the following effects (A) to (D) can be achieved.

(A) In the configuration (1), from the viewpoint of the equivalent circuit, each memory cell includes a parallel electrical connection of the cell transistor, a resistive element, and a variable-resistance element, and each memory cell is electrically connected in series in the stacking direction to form the string. With this configuration, even when a resistivity of the variable-resistance film deviates from the desired resistivity, the desired heat generation and temperature rise can still be achieved in the selected memory cell, and the variable-resistance film can be heated to a desired temperature or higher to cause the desired change in resistance. As a result, a range of materials that can be used as the variable-resistance film can be expanded.

(B) As the operation, the selected word line is set to a low voltage to turn off the selected cell transistor, and the word line of the other non-selected memory cell is set to a high voltage to turn on the cell transistor of the non-selected memory cell. When the voltage is applied to both ends of the string, in the non-selected memory cell, the current flows through the channel semiconductor film, and the current flow on the variable-resistance film side is made difficult because the current is blocked by the resistor film. Thus, the phase change of the variable-resistance film of the non-selected memory cells does not occur, and data stored therein is maintained. In the selected memory cell, since the cell transistor is turned off and the channel semiconductor film has much higher resistance than the resistor film, a current flows to the variable-resistance film side. The resistor film has a thickness greater than that of the variable-resistance film, e.g., 10 nm or more, and since the thickness of the variable-resistance film is smaller than thickness of the resistor film, the amount of current that enters the resistor film from the channel semiconductor film and flows to the variable-resistance film is small. Most of the current entering the resistor film flows in the stacking direction and returns to the channel semiconductor film side at the boundary with the adjacent cell which has a channel semiconductor film at low resistance. Then, a current flows to the cell string end through the channel semiconductor film of the non-selected memory cell.

(C) Due to the effect (B), in the selected memory cell, the variable-resistance film adjacent to the resistor film is heated to a desired temperature (for example, about 900 K) by the temperature rise due to the heat generation P=IV by the current I flowing through the resistor film and the voltage V applied to the resistor film, and as a result, the variable-resistance film is melted. After that the voltage difference between both ends of the string is gradually reduced to perform gradual cooling, so that a crystalline state can be obtained, and the resistance of the variable-resistance film can be lowered (i.e., the set operation can be performed). Alternatively, after melting, the amorphous state can be achieved by rapidly reducing the voltage difference between both ends of the string and rapidly cooling the string, and the resistance of the variable-resistance film can be increased (i.e., the reset operation can be performed).

(D) Due to the effect (C), even though an electric resistivity of the variable-resistance film such as the phase change material is low to some degree, and the current does not flow through the variable-resistance film, the operation can still be performed when the resistor film is made of high-resistance material. For example, this embodiment can be said to be effective because the electric resistivity of the phase change material such as GeSbTe tends to decrease when the temperature thereof is raised to near the melting point thereof.

It is preferred that the film thickness of the resistor film is larger than the film thickness of the variable-resistance film, and it is preferred that the film thickness of the resistor film is 10 nm or more.

In addition, the material of the resistor film is preferably a material having an electrical conductivity of about 4 S/cm to 40 S/cm, and for example, a Ge material containing an impurity such as P, As, Sb, or Bi is preferred.

In addition, it is more desirable that: the semiconductor storage device has a channel semiconductor film in which an impurity region of the channel semiconductor film facing the word line is low, so that the cell transistor is easily cut off, and an impurity region of the channel semiconductor film facing the insulating layer between the word lines is high and the thickness is large, so that the resistance of the channel semiconductor film is low when the channel semiconductor film is diverted to the high-resistance state.

Hereinafter, the embodiments are described with reference to the drawings. Prior to describing the embodiments, a problem with a prior device related to the embodiment and an example of a proposed solution will be briefly described.

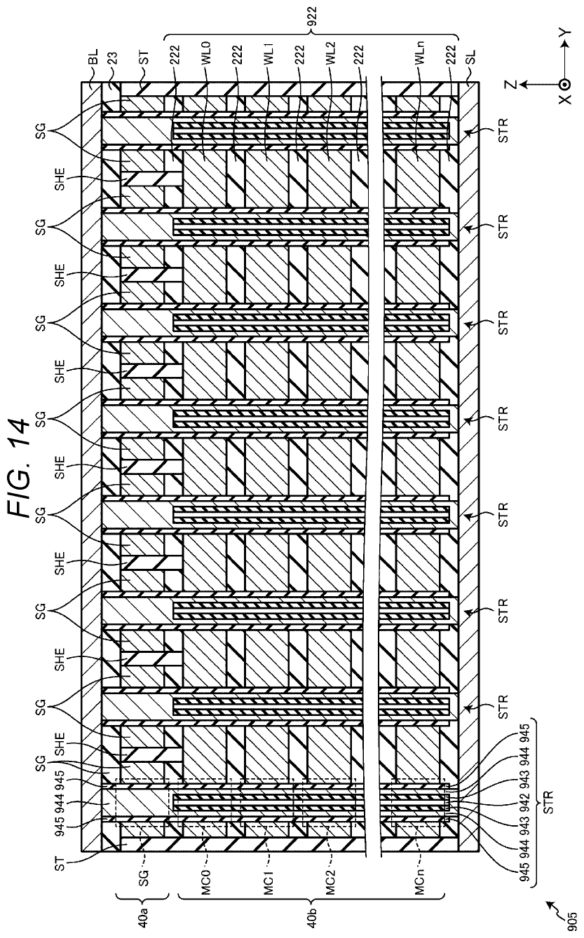

The memory cell array 905 of the prior device is shown in FIG. 14. FIG. 14 is a cross-sectional view showing the configuration of the memory cell array 905. In FIG. 14, an extending direction of the bit line BL is a Y direction, a stacking direction of the memory cell MC is a Z direction, and a direction perpendicular to the Y direction and the Z direction is an X direction. The memory cell array 905 is configured such that a columnar strings STR are two-dimensionally arranged in an XY plane on a +Z side of the substrate (not shown), and the stacked body 922 is penetrated by the columnar strings STR to form a three-dimensional memory cell array. In each string STR, in the cross-sectional view, a core insulating film 942, a variable-resistance film 943, a channel semiconductor film 944, and an insulating film 945 are concentrically arranged in this order from the center to the outside.

Each memory cell MC in the memory cell array 905 includes, equivalently, a parallel connection of the cell transistor and the variable-resistance element. In order to select the memory cell, an L level is supplied to the selected word line WL2, and an H level is supplied to the non-selected word lines WL0 to WL1, WL3 to WLn, and a select gate SG. The source line SL is set to 0 V, and the bit line BL is set to the H level. As a result, the cell transistor is turned off in the selected memory cell, and a voltage is applied to the variable-resistance film 943. The cell transistor is turned on in the non-selected memory cell, and substantially no voltage is applied to the variable-resistance film 943.

At this time, first, when a resistance of the variable-resistance film 943 is sufficiently larger than an on-resistance of the channel semiconductor film 944, a current flows through the channel semiconductor film 944 in the non-selected memory cell MC in which the cell transistor is turned on. In the selected memory cell MC in which the cell transistor is off, a current does not flow through the channel semiconductor film 944, and instead the current flows through the variable-resistance film 943.

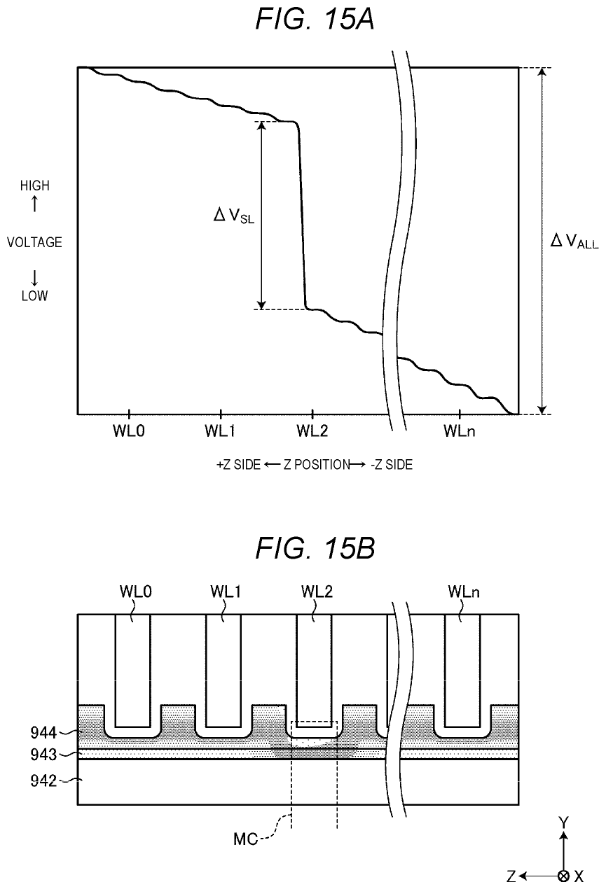

At this time, second, when the resistance of the variable-resistance film 943 of the selected memory cell MC is large to some degree, as shown in FIG. 15A and FIG. 15B, a certain voltage drop ΔV_{SL} occurs across the variable-resistance film 943 of the selected memory cell MC with respect to a voltage drop ΔV_{ALL} occurring across the entire string STR, and the reset operation or the set operation can be achieved in the selected memory cell MC by the heat generation in the selected memory cell MC. When the resistance of the variable-resistance film 943 of the selected memory cell MC is further increased, a voltage drop ΔV_{SL} is large, but the current is small, so that the temperature rise is small. When the resistance of the variable-resistance film 943 is low, a voltage drop ΔV_{SL} is reduced, and the temperature rise and the heat generation in the selected memory cell MC is small, so that the proper operation cannot be performed on the selected memory cell MC. FIG. 15A shows a voltage change with respect to a Z position of the channel semiconductor film 944 in a graph, and FIG. 15B is a YZ cross-sectional view that shows a change in a current density distribution in the channel semiconductor film 944 with respect to the Z position of the channel semiconductor film 944. In FIG. 15A and FIG. 15B, the Z positions are aligned with each other. In FIG. 15A and FIG. 15B, the memory cell MC corresponding to the word line WL2 is the selected memory cell.

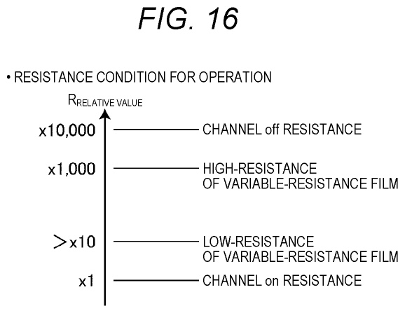

As shown in FIG. 16, the resistance of the variable-resistance film 943 has an appropriate range. A resistance in a high-resistance state and a resistance in a low-resistance state of variable-resistance film 943 are required to be values between an on-resistance and an off-resistance of the cell transistor. FIG. 16 is a diagram showing a resistance condition of the channel semiconductor film 944 for operation. The on-resistance of the cell transistor is a resistance of the channel semiconductor film 944 in a state where the cell transistor is turned on. The off resistance of the cell transistor is the resistance of the channel semiconductor film 944 in a state where the cell transistor is off.

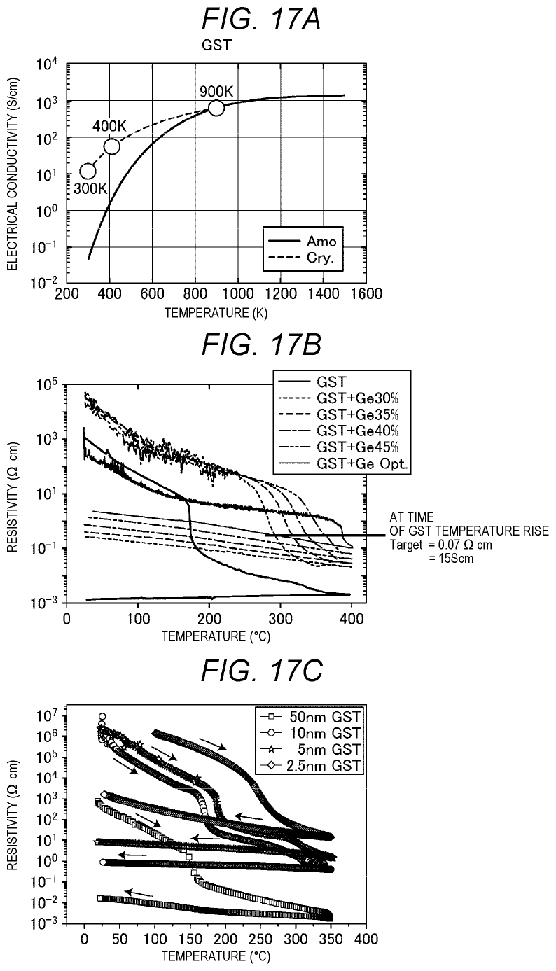

A feature of the material of the variable-resistance film 943 (for example, phase change material) is that its electrical conductivity increases at a high temperature as shown in FIG. 17A. It is difficult to obtain a desired low electrical conductivity near a melting operation at 900 K in a pure Ge₂Sb₂Te₅ (GST) structure.

In addition, it is also conceivable to dope the resistance change film 943 such as a phase change material with an impurity (for example, Ge) to increase the resistivity of the resistance change film 943, thereby generating heat in the resistance change film 943 to raise the temperature to a desired temperature (for example, near 900 K) and perform a melting operation. For example, FIG. 17B is the resistivity-temperature characteristics of the phase change material disclosed in V. Sousa, G. Navarron. Castellani, M. Coue, O. Cucto, C. Sabbione, P. Noe, L. Perniola, S. Blonkowski, P. Zuliani, R. Annunziata “Operation Fundamentals in 12 Mb Phase Change Memory Based on Innovative Ge-rich GST Materials Featuring High Reliability Performance”, 2015 Symposium on VLSI Technology Digest of Technical Papers, p. T98-T99, and shows a change in the characteristics when an impurity (for example, Ge) is doped into the phase change material. As shown in FIG. 17B, a method of increasing the electrical resistivity by adding an impurity to GST is difficult to control due to the fact that the impurity is likely to be excessively doped.

Alternatively, it is also conceivable to heat the variable-resistance film 943 by making the variable-resistance film 943 smaller so as to increase the resistivity of the variable-resistance film 943 and raise the temperature to the desired temperature (for example, near 900 K) and perform the melting operation. For example, FIG. 17C is a resistivity-temperature characteristic of the phase change material disclosed in Huai-Yu Cheng, Simone Raoux and Yi-Chou “hen, “The impact of film thickness and melt-quenched phase on the phase transition characteristics of Ge2″b2Te5”, J. Appl. Phys. 107, 074308 (2010), p. 074308-1 to 074308-9. FIG. 17C shows a change of the characteristics when the film of the phase change material is made small. This method is difficult to control as shown in FIG. 17C, because the electric resistivity changes depending on a film thickness and a temperature of GST. and the method requires electrical resistivity adjustment every time the memory hole size changes in new designs.

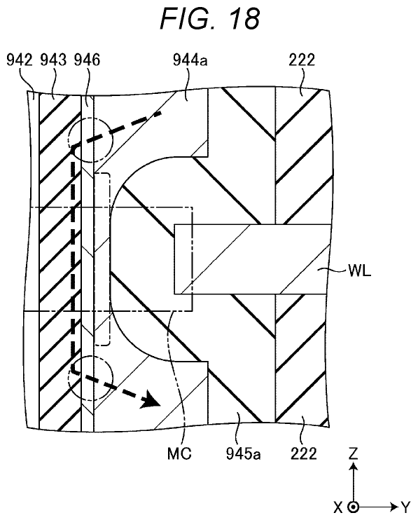

In order to solve the above problem, FIG. 18 shows a structural example of the memory cell MC that has been considered. When the electric resistivity of the variable-resistance film 943 such as the phase change material is lower than the desired electric resistivity, in this structure where a resistor film 946 such as the high-resistance material is inserted between the channel semiconductor film 944a and the resistive change film 943, the resistor film 946 generates heat to raise the temperature. In this example where the variable-resistance film 943 has a thickness of 2 nm, a resistor film 946 having a thickness of 8 nm is inserted.

In this structure, since the resistor film 946 is small (i.e., thin), as indicated by an arrow of a dotted line, the current that enters the resistor film 946 from the channel semiconductor film 944a flows into the variable-resistance film 943 having a low resistance at an upper part of the selected memory cell MC. The current then passes through the resistor film 946 from the variable-resistance film 943 and flows into the channel semiconductor film 944a at a lower part of the selected memory cell MC. A problem arises in that heat generation peak points occur above and below the selected memory cell MC, and it is difficult to concentrate the temperature rise of the variable-resistance film 943 of the selected memory cell MC.

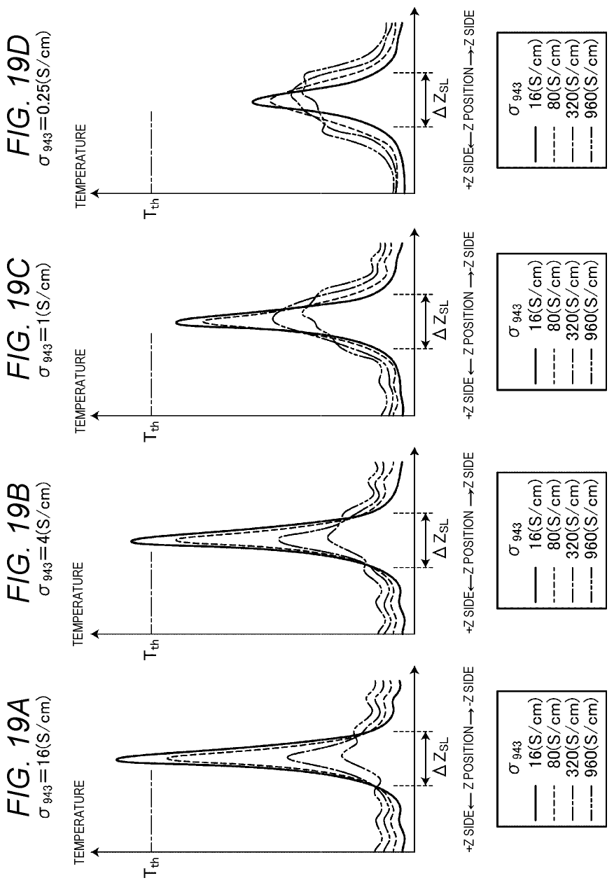

This state is shown in FIG. 19. In FIG. 19A to FIG. 19D, in a case where the electrical conductivity σ₉₄₆ of the resistor film 946 is lowered from 16 (S/cm) to 4 (S/cm) to 1 (S/cm) to 0.25 (S/cm) at a temperature of 900 K, the temperature at the Z position is shown by varying the electrical conductivity σ₉₄₃ of the variable-resistance film 943 in each of FIG. 19A to FIG. 19D.

In each of FIG. 19A to FIG. 19D, the solid line indicates a temperature distribution in the Z direction of the variable-resistance film 943 at the time of writing in a case where the electrical conductivity σ₉₄₃ of the variable-resistance film 943 is 16 (S/cm) at a temperature of 900K and 0.266 (S/cm) at a temperature of 300K. The dotted line indicates the temperature distribution in the Z direction of the variable-resistance film 943 at the time of writing in a case where the electrical conductivity σ₉₄₃ of the variable-resistance film 943 is 80 (S/cm) at a temperature of 900 K and 1.33 (S/cm) at a temperature of 300 K. A one-dot chain line indicates the temperature distribution in the Z direction of the variable-resistance film 943 at the time of writing in a case where an electrical conductivity 943 of the variable-resistance film 943 is 320 (S/cm) at a temperature of 900 K and 5.3 (S/cm) at a temperature of 300 K. A two-dot chain line indicates the temperature distribution in the Z direction of the variable-resistance film 943 at the time of writing in a case where an electrical conductivity σ₉₄₃ of the variable-resistance film 943 is 960 (S/cm) at a temperature of 900 K and 16 (S/cm) at a temperature of 300 K.

As shown in FIG. 19A, in a case where the electrical conductivity of the resistor film 946 is σ₉₄₆=16 S/cm and the electrical conductivity of the variable-resistance film 943 is σ₉₄₃, the temperature rises to a desired temperature Tth (for example, about 900 K) in a Z position range ΔZ_{SL} of the selected memory cell. When the electrical conductivity σ₉₄₃ of the variable-resistance film 943 such as SGT is increased from 16 (S/cm) to 80 (S/cm) to 320 (S/cm) to 960 (S/cm), a peak temperature drops from the desired temperature Tth.

On the other hand, as shown in FIG. 19D, when the electrical conductivity σ₉₄₆ of the resistor film 946 is reduced to 0.25 S/cm and the electrical conductivity σ₉₄₃ of the variable-resistance film 943 is increased to 960 (S/cm), heat is generated in a part of the resistor film 946, but the heat generation is divided into two parts in the vertical direction (in this drawing, in the horizontal direction) of the selected memory cell MC, and as a result, a problem occurs in that the temperature peak does not rise to the desired temperature Tth (for example, about 900 K).

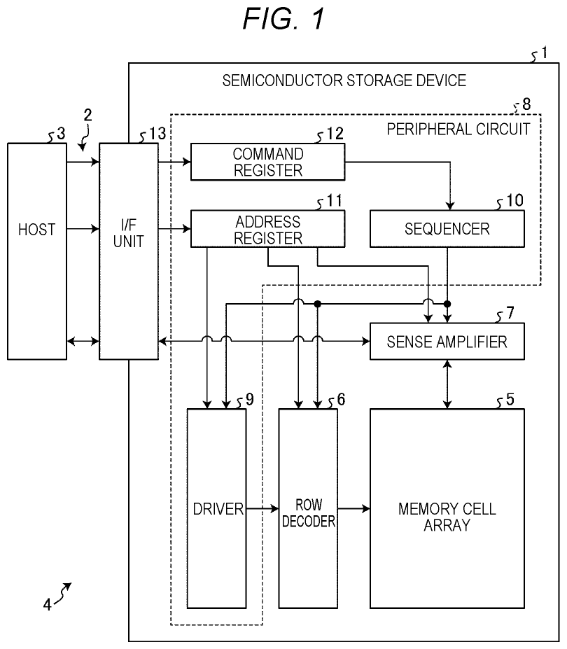

Next, an embodiment will be described. A semiconductor storage device 1 according to an embodiment can be configured as illustrated in FIG. 1. FIG. 1 is the diagram showing the schematic configuration of the semiconductor storage device 1. The semiconductor storage device 1 can be connected to a host 3 via a communication medium 2. The semiconductor storage device 1 is, for example, a resistive random access memory. The communication medium 2 is, for example, a serial communication line. The host 3 is, for example, a controller or a CPU. A configuration including the semiconductor storage device 1, the communication medium 2, and the host 3 may be configured as a memory system 4. The memory system may be a memory card such as an SD card, a storage system such as an SSD, or an eMMC device. The host 3 may be a controller or a CPU.

The semiconductor storage device 1 has a memory cell array 5, a row decoder 6, a sense amplifier 7, a peripheral circuit 8, and an interface unit (I/F unit) 13. The peripheral circuit 8 includes a driver 9, a sequencer 10, an address register 11, and a command register 12. In the memory cell array 5, a plurality of memory cells are arranged. The plurality of memory cells are accessible using a plurality of word lines and a plurality of bit lines. Each of the plurality of word lines is associated with a row address. Each of the plurality of bit lines is associated with a column address. A command register 12 stores a command included in a host request received from the host 3 via the I/F unit 13. An address register 11 stores an address included in a host request received from the host 3 via the I/F unit 13.

The sequencer 10 executes a command stored in the command register 12 and controls a write operation or a read operation of data with respect to the memory cell array 5. The row decoder 6 decodes the address stored in the address register 11 and can select a word line corresponding to the decoded row address in response to the control by the sequencer 10. The driver 9 generates a voltage for selecting the word line and supplies the voltage to the row decoder 6 in response to the control by the sequencer 10. The sense amplifier 7 decodes the address stored in the address register 11 in response to the control by the sequencer 10, and can select a bit line corresponding to the decoded column address.

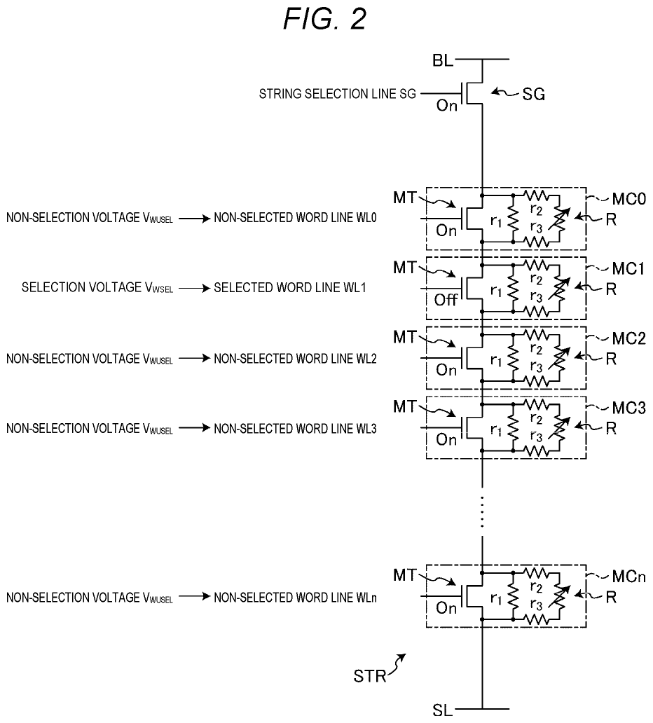

A plurality of memory cells are arranged three-dimensionally in the memory cell array 5, and is referred to as a chain-connected memory. In the chain-connected memory, a plurality of memory cells MC0 to MCn (n is any integer equal to or more than 4) are connected in series to form a string STR as shown in FIG. 2. FIG. 2 is a circuit diagram showing the configuration of the string STR.

The memory cell MC includes a parallel connection of a variable-resistance element R, a resistive element r1, and a serial connection of a cell transistor MT and a resistive elements r2 and r3. One end of the variable-resistance element R is connected to one end of the resistive element r1 through the resistive element r2. The other end of the variable-resistance element R is connected to the other end of the resistive element r1 through the resistive element r3.

One end of the memory cell MC is respectively connected to a source (or drain) of the cell transistor MT, one end of the resistive element r1, and one end of the resistive element r2. The other end of the resistive element r2 is connected to one end of the variable-resistance element R. The other end of the memory cell MC is respectively connected to the drain (or source) of the cell transistor MT, the other end of the resistive element r1, and one end of the resistive element r3. The other end of the resistive element r3 is connected to the other end of the variable-resistance element R.

The variable-resistance element R has a resistance value that can be changed between the high-resistance state and the low-resistance state, and functions as a variable resistive element. When a resistance value of the variable-resistance element R in the high-resistance state is represented by R_{HR<R1}} and a resistance value of the variable-resistance element R in the low-resistance state is represented by R_{LR<R2}}, the resistance values r1, r2, and r3 of the resistive elements r1, r2, and r3 satisfy the following Expression 1 and Expression 2.

$$r 1 < r 2 + {R}_{HR < R} + r 3 \qquad Expression 1$$

$$r 2 + {R}_{LR < R} + r 3 < r 1 \qquad Expression 2$$

When the resistance conditions for operation (see FIG. 16) are combined with Expression 1 and Expression 2, the following Expression 3 is established.

$$Ron < r 2 + {R}_{LR} + r 3 < r 1 < r 2 + {R}_{HR} + r 3 < Roff \qquad Expression 3$$

In Expression 3, Ron is a resistance of a channel semiconductor film 44 in an on-state of the cell transistor MT. Roff is a resistance of a channel semiconductor film 44 in an off-state of the cell transistor MT.

The bit line BL is connected to one end of the plurality of memory cells MC0 to MCn connected in series through a string select transistor SG, and the source line SL is connected to the other end to configure a string STR. The word lines WL0 to WLn are connected to gates of cell transistors MT of the memory cells MC0 to MCn.

The row decoder 6 supplies a selection voltage V_{WSEL} to the selected word line WL and supplies a non-selection voltage V_{WUSEL} to the non-selected word line WL among the plurality of word lines WL. As a result, the cell transistor MT of the selected memory cell MC is turned off, and the cell transistor MT of the non-selected memory cell MC is turned on. When the voltage is applied between the bit line BL and the source line SL by the sense amplifier 7, the cell transistor MT of the non-selected memory cell MC is turned on, and the voltage is not applied to the variable-resistance element R of the non-selected memory cell MC. When the cell transistor MT of the selected memory cell MC is turned off, almost all of the applied voltage between the bit line BL and the source line SL can be applied to the serial connection of the resistive element r1 of the selected memory cell MC, the cell transistor MT, and the resistive elements r2 and r3.

As a result, when the variable-resistance element R is in a high-resistance state, Expression 1 is established, and the current of the selected memory cell MC mainly flows to the resistive element r1, the resistive element r1 generates heat, and the variable-resistance element R can be heated to a predetermined temperature and melted. As a result, data can be written to the variable-resistance element R of the selected memory cell MC.

Alternatively, when the variable-resistance element R is in a low-resistance state, Expression 2 is established, and the current of the selected memory cell MC mainly flows to the variable-resistance element R, the variable-resistance element R generates heat, and the variable-resistance element R can be heated to a predetermined temperature and melted. As a result, data can be written to the variable-resistance element R of the selected memory cell MC.

In addition, by detecting the voltage V and the current I of the selected memory cell MC, the resistance of the variable-resistance element R of the selected memory cell MC can be detected, and thus data can be read.

This structure includes a configuration in which the plurality of memory cells MC are connected in a chain configuration, and thus can be achieved with a structure similar to a three-dimensional flash.

In a three-dimensional flash memory cell array, an insulating film between a cylindrical channel semiconductor film and a plate-shaped word line WL is a gate insulating film that includes a charge accumulation film. In the memory cell array 5 of the embodiment, the gate insulating film is changed to an insulating film that does not include a charge accumulation film. In addition, a resistor film and a variable-resistance film are embedded inside the cylindrical channel semiconductor film. As a result, the resistive change type memory cell array 5 can be configured three-dimensionally. In this configuration, when the cell transistor MT of the selected memory cell MC is selectively turned off, it is possible to access the variable-resistance film (variable-resistance element R) of the selected memory cell MC. In this manner, the memory cell array 5 of the three-dimensional flash type is formed by stacking the plurality of word lines WL and forming a memory hole by batch processing, and the gate insulating film, the channel semiconductor film, the resistor film, the variable-resistance film, and the like are embedded in the memory hole, so that the cost can be greatly reduced.

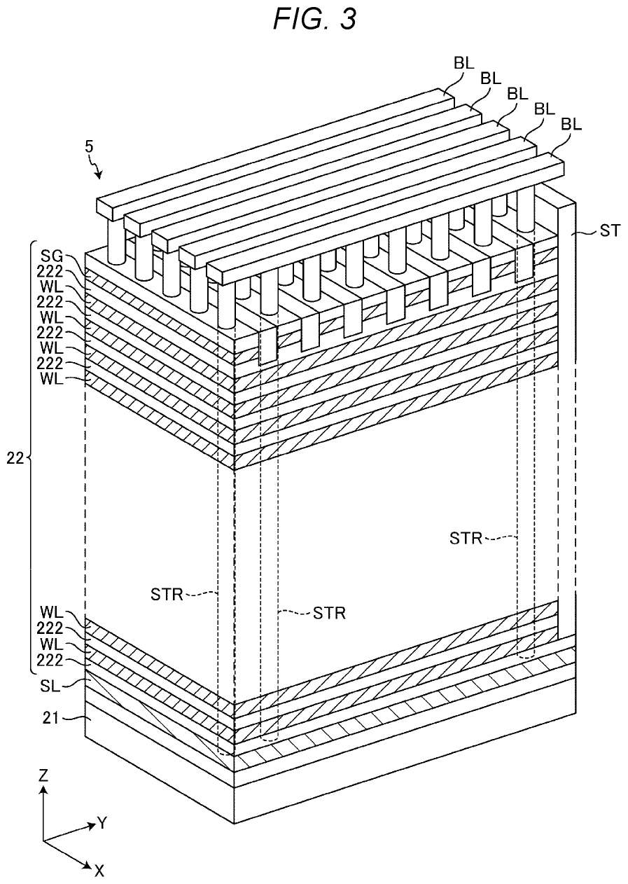

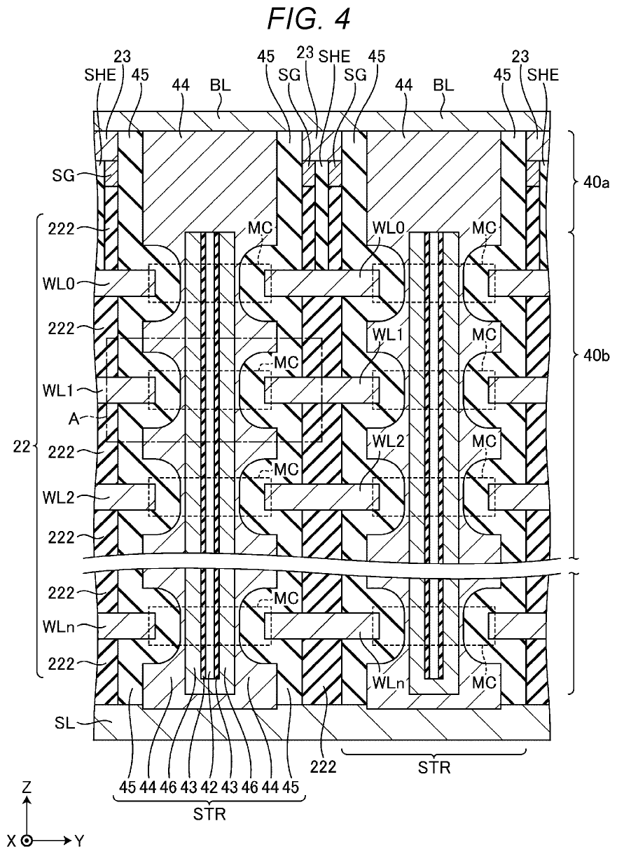

For example, the memory cell array 5 can be configured as shown in FIG. 3 and FIG. 4. FIG. 3 is a perspective view showing a schematic configuration of the memory cell array 5. FIG. 4 is a cross-sectional view showing a configuration of the memory cell array 5. In FIG. 3 and FIG. 4, the extending direction of the bit line BL is the Y direction, the stacking direction of the memory cell transistor MC is the Z direction, and the direction perpendicular to the Y direction and the Z direction is the X direction.

In the memory cell array 5, a plurality of stacked layers of the word line WL and the insulating layer 222 are alternately stacked in the Z direction to form the stacked body 22. The word line WL may be formed of a conductive layer extending in a substantial plate shape in the XY plane. The insulating layer 222 extends in a substantially plate shape in the XY plane. A string STR is formed in the memory hole in the stacked body 22. In the string STR, the gate insulating film, the channel semiconductor film, the resistor film such as the high-resistance material, the variable-resistance film such as the phase change material, and the core insulating film is formed by sequentially forming in order from the outer periphery to the inner periphery in the memory hole. A plurality of memory cells are formed at a plurality of intersection positions where the plurality of word lines WL and the string STR intersect. The plurality of the string STRs are arranged in the XY plane.

As shown in FIG. 3, on the +Z side of the substrate 21, the columnar string STR is arranged two-dimensionally in the XY plane, and the stacked body 22 is configured to be penetrated by the columnar string STR to form a three-dimensional arrangement of memory cells.

In this configuration, from the viewpoint of the equivalent circuit, each memory cell MC includes electrically parallel connections of the cell transistor MT, the resistive element r1 corresponding to the resistor film, and the variable-resistance element R corresponding to the variable-resistance film (refer to FIG. 2), and the memory cells are electrically connected in series in the Z direction to form a chain-connected type string STR.

The source line SL is configured with a plate-shaped conductive film extending in the XY plane. The source line SL may be formed of a material containing a metal as a main component or may be formed of a semiconductor to which conductivity is imparted. Alternatively, the source line SL (not shown) may be disposed in a vicinity of a surface of the substrate 21 and may be configured as a semiconductor region containing impurities and imparted with conductivity. A predetermined voltage may be supplied to the source line SL from the peripheral circuit 8.

In addition, the plurality of stacked bodies including the stacked body 22 may be disposed on the +Z side of the substrate 21. The plurality of stacked bodies is arranged at positions spaced apart in the Y direction from each other with a separation portion ST interposed therebetween. The separation portion ST has at least a surface in contact with the stacked body 22 formed of the insulating material, and electrically separates the stacked body 22 from the other stacked bodies. The separation portion ST has a substantially fin shape extending along the XZ plane. Although not shown, the separation portion ST may be have two insulating parts having a flat plate shape in the XZ plane and an electrode part having a flat plate shape in the XZ plane and interposed between the two insulating parts. The electrode portion may be used as a part of a predetermined wiring for supplying a voltage to the source line SL.

In the stacked body 22, the word line WL and the insulating layer 222 are alternately and repeatedly stacked. The word line WL is configured with a plate-shaped conductive film extending in the XY plane. In the stacked body 22, the plurality of word line WLs are arranged apart from each other in the Z direction. Each word line WL is formed of a material containing a conductive material (for example, a metal such as tungsten) as a main component. Each insulating layer 222 is formed of a material containing an insulating material (for example, silicon oxide) as a main component.

A string selection line SG is stacked on the uppermost insulating layer 222 of the stacked body 22. The string selection line SG is configured with the plate-shaped conductive film extending in the XY plane. The string selection line SG may be formed of a material containing a conductive material (for example, a metal such as tungsten) as a main component. Each string selection line SG is divided in the Y direction by an isolating film SHE. The isolating film SHE is provided above the word line WL (+Z side), extends in the Y direction and Z direction, and reaches the uppermost insulating layer 222 of the stacked body 22. The isolating film SHE is formed of the insulating material (for example, silicon oxide). Accordingly, each string selection lines SG are electrically insulated from each other.

The string STR has a columnar shape and penetrates the stacked body 22 in the Z direction. Each string STR extends in the Z direction. The plurality of string STRs may be arranged two-dimensionally in the XY plane. Each string STR includes a columnar main portion 40b and a columnar upper portion 40a. The columnar upper portion 40a is disposed on a +Z side of the columnar main portion 40b and is connected to the columnar main portion 40b.

A string select transistor SG is configured at a position where the columnar upper portion 40a and the string selection line SG intersect. The cell transistor MT of the memory cell MC is configured at a position where the columnar main portion 40b and the word line WL intersect.

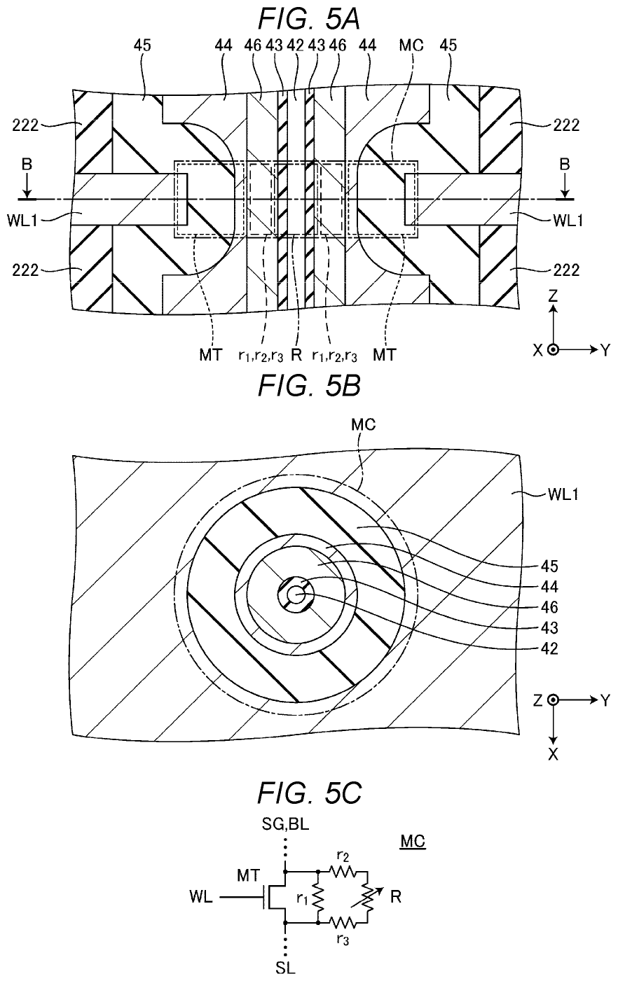

As shown in FIG. 5A and FIG. 5B, the columnar main portion 40b has the core insulating film 42, the variable-resistance film 43, the resistor film 46, the channel semiconductor film 44, and the insulating film 45. FIG. 5A is a cross-sectional view showing a configuration of the memory cell MC. FIG. 5B is a plan view showing the configuration of the memory cell MC, and shows a cross section taken along a line B-B of FIG. 5A. FIG. 5C shows an equivalent circuit of each memory cell MC.

The core insulating film 42 is disposed in a vicinity of a central axis of the string STR and extends along the central axis of the string STR. The core insulating film 42 is formed of a material containing an insulating material (for example, silicon oxide) as a main component. The core insulating film 42 has a substantially I-shaped cross section in a ZY cross-sectional view and has a substantially I-shaped cross section in a ZX cross-sectional view.

The variable-resistance film 43 is disposed between the core insulating film 42 and the word line WL, and surrounds the core insulating film 42 from the outside, and extends along the central axis of the string STR. The variable-resistance film 43 may be formed of a material that exhibits variable-resistance characteristics by phase change. For example, the variable-resistance film 43 may be formed of a chalcogenide-based material (Ge, Sb, Te). The variable-resistance film 43 has a generally columnar shape and has a substantially cylindrical shape.

The variable-resistance film 43 may be formed of a material and/or a film thickness that satisfies the resistance condition for operation (refer to Expression 3). It is required that the resistance of the resistive change film 43 in the high-resistance state and the resistance of the variable-resistance film 43 in the low-resistance state are values between the on-resistance and the off-resistance of the cell transistor MT. The on-resistance of the cell transistor MT is the resistance of the channel semiconductor film 44 in a state where the cell transistor MT is turned on. The off-resistance of the cell transistor MT is the resistance of the channel semiconductor film 44 in a state where the cell transistor MT is off.

The resistor film 46 may be formed of the material and/or the film thickness that satisfies the resistance condition for operation (see Expression 3). The resistor film 46 is disposed between the variable-resistance film 43 and the channel semiconductor film 44, and surrounds the variable-resistance film 43 from the outside, and extends along the central axis of the string STR. The resistor film 46 may be formed of a material having an electrical conductivity of about 4 S/cm to 40 S/cm. The resistor film 46 is formed of, for example, a material in which impurities such as P, As, Sb, and Bi are contained in a Ge atom. Ge has good compatibility with a phase change material (for example, GeSbTe). The resistor film 46 has a generally columnar shape and has a substantially cylindrical shape. The thickness of the resistor film 46 is greater than the thickness of the variable-resistance film 43.

The channel semiconductor film 44 is disposed between the variable-resistance film 43 and the word line WL, and surrounds the resistor film 46 from the outside and extends along the central axis of the string STR. The channel semiconductor film 44 may be formed of a material containing a semiconductor (for example, polysilicon) as a main component. The channel semiconductor film 44 has a substantially cylindrical shape having a substantially circular groove at the Z position of the word line WL. The thickness of the channel semiconductor film 44 facing the word line WL in the memory cell MC is smaller than the thickness of the portion of the channel semiconductor film between the neighboring memory cells MC. The lower end (the end portion on the −Z side) of the channel semiconductor film 44 is electrically connected to the source line SL.

The insulating film 45 is disposed between the channel semiconductor film 44 and the word line WL, and surrounds the variable-resistance film 43 from the outside, and extends along the central axis of the string STR. The insulating film 45 is formed of a material containing an insulating material (for example, silicon oxide) as a main component.

In the columnar main portion 40b, a region intersecting with the word line WL, which is surrounded by a one-dot chain line in FIG. 5A, functions as the memory cell MC. Among the regions functioning as the memory cell MC, a portion in which the word line WL/the insulating film 45/the channel semiconductor film 44 are stacked in the radial direction of the string STR as shown by the dotted line with a small pitch in FIG. 5A functions as the cell transistor MT, and the variable-resistance film 43 functions as the variable-resistance element R as shown by an alternate long and two-dot chain line in FIG. 5A. As shown by the dotted line with a large pitch in FIG. 5A, the resistor film 46 functions as a resistive element r1 connected in parallel to the variable-resistance element R and resistive elements r2 and r3 connected in series to the variable-resistance element R (see FIG. 5C).

The columnar upper portion 40a shown in FIG. 4 is disposed on the columnar main portion 40b (+Z side). The columnar upper portion 40a extends from the Z position between the word line WL0 and the string selection line SG to the Z position higher than the string selection line SG. The string select transistor SG is configured at a position where the columnar upper portion 40a intersects the string selection line SG. The columnar upper portion 40a has the channel semiconductor film 44 and the insulating film 45.

An interlayer insulating film 23 is disposed above (on the +Z side) the string selection line SG. The interlayer insulating film 23 is formed of a material containing an insulating material (for example, silicon oxide) as a main component.

The Bit line BL is disposed on the interlayer insulating film 23. The bit line BL is formed of a line-shaped conductive film extending in the Y direction. The bit line BL may be formed of a material containing a conductive material (for example, a metal such as tungsten, copper, or aluminum) as a main component.

A contact plug (not shown) may be disposed between the bit line BL and the channel semiconductor film 44. In this case, the contact plug can be in contact with the bit line BL at an upper end, be in contact with the channel semiconductor film 44 at a lower end, and electrically couple the bit line BL and the channel semiconductor film 44. The contact plug is formed of a material containing a conductive material (for example, a metal such as tungsten) as a main component.

With this configuration, even when the electric resistivity of the variable-resistance film 43 such as a phase change material is low to some extent, as long as the resistor film 46 such as a high-resistivity material has a thickness that is greater than that of the variable-resistance film 43, unintentional current flow in the variable-resistance film 43 can be avoided. For example, the variable-resistance film 43 such as GeSbTe tends to decrease in the electric resistivity when the temperature rises near the melting point. Therefore, it can be said that the present embodiment is effective. In the present embodiment, it is effective that the thickness of the resistor film 46 is greater than the thickness of the variable-resistance film 43, and it is effective that the thickness of the resistor film 46 is 10 nm or more. In addition, the operation is performed even in next-generation designs in which the thickness of the variable-resistance film 43 changes, and the electrical conductivity of the variable-resistance film 43 changes. That is, a range of the operable electrical conductivity of the variable-resistance film 43 is widened. In addition, in the present embodiment, the channel semiconductor film 44 at approximately the same Z position as the word line WL has a low impurity node, and the cell transistor MT is easily cut off. The channel semiconductor film 44 at the Z position between the word lines WL has a high impurity node and the thickness of the channel semiconductor film is large. It is more preferable for the resistance of the channel semiconductor film 44 when the current is diverted from the channel semiconductor film 44 to the resistor film 46 to be low.

For example, the word line WL corresponding to the selected memory cell MC is set to a low voltage, and the cell transistor MT of the selected memory cell MC is turned off. The word line WL corresponding to the non-selected memory cell MC is set to a high voltage, and the cell transistor MT of the non-selected memory cell MC is turned on. It is assumed that a voltage is applied to both ends of the string STR.

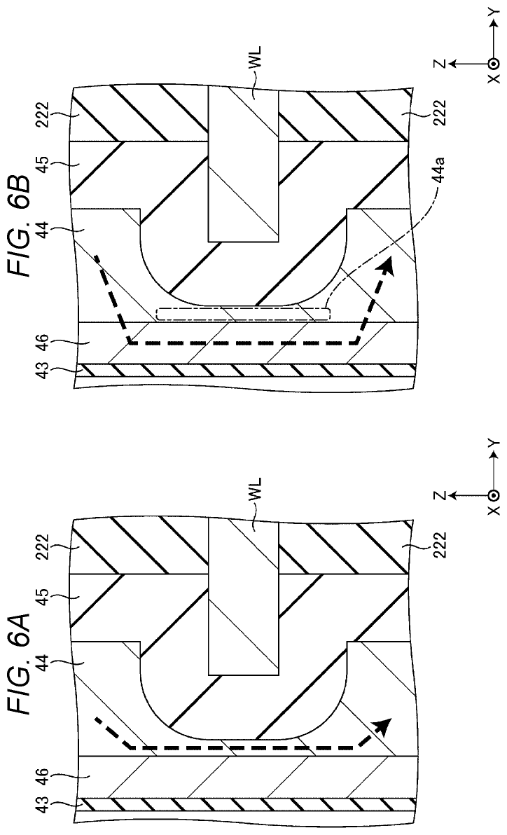

In the non-selected memory cell MC, as indicated by a dotted line in FIG. 6A, the cell transistor MT is in an on-state, a current flows through the channel semiconductor film 44, and the current is difficult to flow through the variable-resistance film 43 because it is blocked by the resistor film 46. In the non-selected memory cell MC, the phase change of the variable-resistance film 43 does not occur, and the data stored therein is maintained.

In the selected memory cell, as indicated by a dotted line in FIG. 6B, the cell transistor MT is in an off state, and the channel region 44a of the channel semiconductor film 44 has a much higher resistance than the resistor film 46. Therefore, a current inevitably flows to the resistor film 46 side. Since the thickness of the resistor film 46 is, for example, 10 nm or more, and the thickness of the variable-resistance film 43 is smaller than the resistor film 46, the current that flows into the variable-resistance film 43 is small, and most of the current flows in the resistor film 46 in the Z direction. The current having flowed through the resistor film 46 of the selected memory cell returns to the channel semiconductor film 44 side. The current flows out to an end portion of the string STR through the channel semiconductor film 44 of the non-selected memory cell MC.

According to the above operation, in the selected memory cell MC, the heat generation P=IV is generated mainly in accordance with the current I flowing through the resistor film 46 and the voltage V applied to the variable-resistance film 43. The temperature of the variable-resistance film 43 of the selected memory cell MC is increased to a desired temperature Tth (for example, about 900 K) by the temperature increase due to the generated heat P, the resistive change film 43 is melted, and then a voltage difference between both ends of the string STR is slowly reduced and the string STR is cooled. As a result, the variable-resistance film 43 can be brought into a crystalline state and can be brought into a low-resistance state (set operation).

Alternatively, after melting, by rapidly reducing the voltage difference between both ends of the string STR and rapidly cooling the string STR is rapidly cooled, the variable-resistance film 43 can be brought into an amorphous state and can be set to a high-resistance state (reset operation).

As described above, in the embodiment, the thickness of the resistor film 46 is greater than the thickness of the variable-resistance film 43 in each string STR of the semiconductor storage device 1. A plurality of memory cells are formed at a plurality of intersection positions where the plurality of word lines WL and the string STR intersect. As a result, when the current is caused to flow through the resistor film 46 to generate heat at the time of writing to each memory cell MC, the temperature of the variable-resistance film 43 can be raised to the desired temperature Tth (for example, 900 K or higher), and the temperature can be slowly decreased (set operation) or rapidly decreased (reset operation). That is, the heat generation and the temperature rise at the time of writing to each memory cell MC are mainly performed by the resistor film 46. As a result, the restriction on the material of the variable-resistance film 43 under the resistance condition for operation (refer to Expression 3) can be relaxed, and the range of the material applicable to the variable-resistance film 43 can be expanded while satisfying the resistance condition for operation. As a result, in the semiconductor storage device 1, a degree of freedom in design can be increased while improving a reliability of the write operation to each memory cell MC. Therefore, the semiconductor storage device 1 can be flexibly designed.

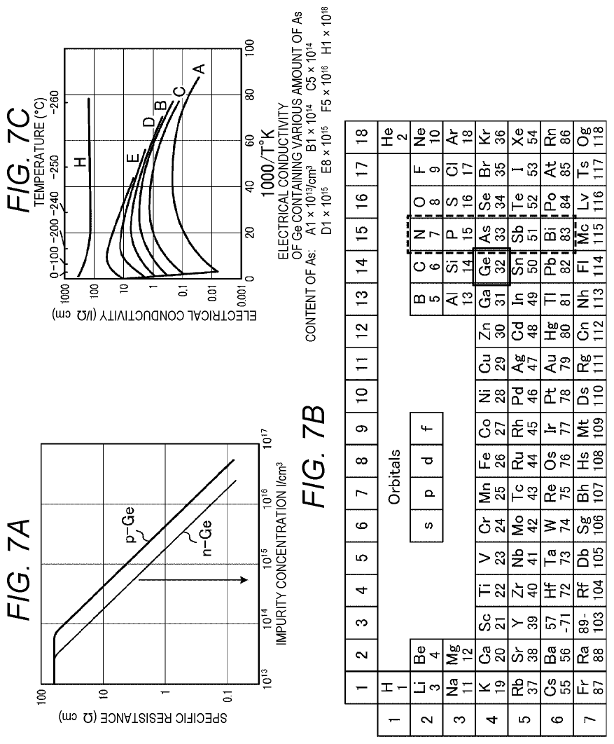

As a first modification example of the embodiment, the resistor film 46 can be formed of any high-resistance material that satisfies the operation resistance condition as shown in Expression 3, and may be formed of a high-resistance material including a Ge atom as shown in FIG. 7A to FIG. 7C, for example. FIG. 7 is a diagram showing a material of a resistor film according to the first modification example of the embodiment. FIG. 7A is a diagram showing a relationship between a specific resistance of a Ge atom and an impurity concentration at 300 K, which is disclosed in Michio Hatoyama, “First Compilation: Electronic Materials, Semiconductor Materials”, “Materials Testing” Vol. 6, No. 41, p. 60 to 69. FIG. 7B is a periodic table of elements. FIG. 7C is a diagram showing a plurality of impurity concentrations having different temperature dependences of the electrical conductivity of the Ge atom described in Michio Hatoyama, “First Compilation: Electronic Materials, Semiconductor Materials”, “Materials Testing” Vol. 6, No. 41, p. 60 to 69.

As the material of the resistor film 46, a material having the electrical conductivity of 4 S/cm or more and 40 S/cm or less at the desired temperature (for example, 900 K or higher) is desirable. From the value of the specific resistance of the Ge atom at 300 K shown in FIG. 7A, the Ge atom can be exemplified as an element in which the electrical conductivity can be 4 S/cm or more and 40 S/cm or less at 900 K. The resistor film 46 may contain the Ge atom. The Ge atom has good compatibility with the material of the variable-resistance film 43 (for example, GeSbTe).

The resistor film 46 may further contain an impurity in order to adjust the electrical conductivity thereof. When the channel semiconductor film 44 is the N-type, as shown by a bold line in the periodic table of FIG. 7B, a material containing an impurity such as P, As, Sb, or Bi in a Ge atom is promising as the material of the resistor film 46 so that the resistor film 46 is the N-type semiconductor. The resistor film 46 may further contain one or more elements selected from the group consisting of P, As, Sb, and Bi as an impurity.

In consideration of the relationship between the specific resistance at 300 K and the impurity concentration shown in FIG. 7A and the temperature dependence of the electrical conductivity shown in FIG. 7C, the impurity concentration (or impurity density) of the resistor film 46 is desirably 1e14/cm³ to 1e16/cm³.

As described above, since the resistor film 46 contains the Ge atom and further contains one or more elements selected from the group consisting of P, As, Sb, and Bi as an impurity, at the time of writing to each memory cell MC, it becomes easier to cause the current to flow to the resistor film 46 and generate heat at the time of writing to each memory cell MC, and increase the temperature of the variable-resistance film 43 to the desired temperature (for example, 900 K or higher). That is, in the semiconductor storage device 1, the heat generation and the temperature rise at the time of writing to each memory cell MC can be mainly performed by the resistor film 46, and the range of the material applicable to the variable-resistance film 43 while satisfying the resistance condition for operation can be expanded.

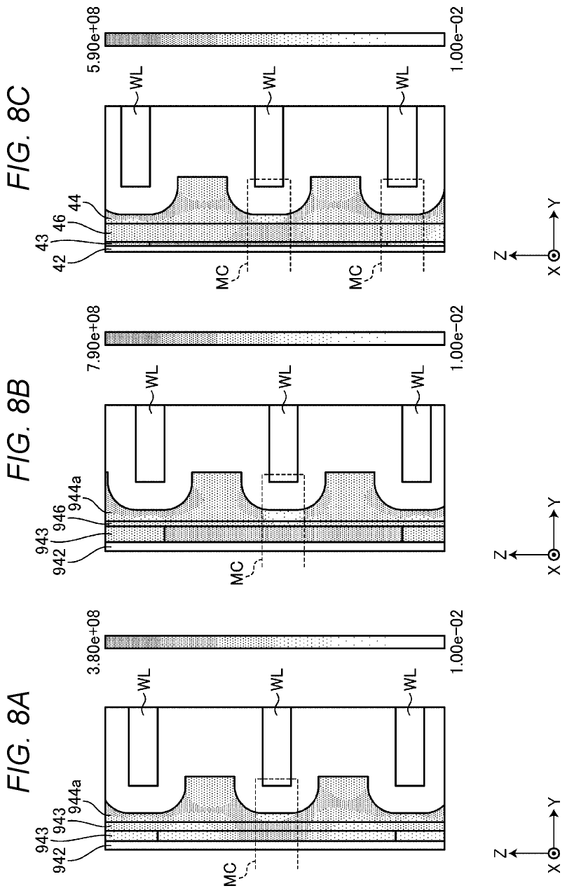

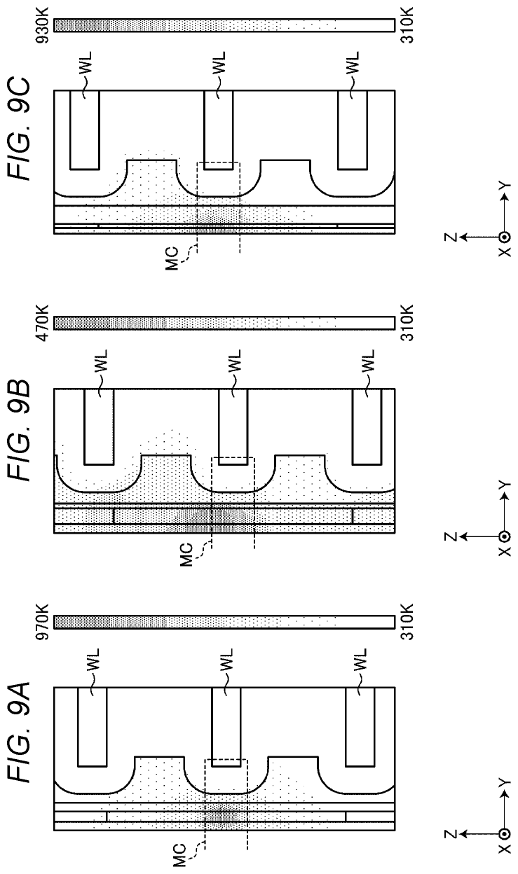

As a second modification example of the embodiment, the selected memory cell MC may operate as shown in FIG. 8C and FIG. 9C.

FIGS. 8A-8C are diagrams showing a current density distribution in the vicinity of the selected memory cell at the time of writing. FIG. 8C shows the current density distribution in the vicinity of the selected memory cell MC in the second modification example of the embodiment. FIG. 8A shows the current density distribution in the vicinity of the selected memory cell MC in the configuration corresponding to FIG. 14. FIG. 8B shows the current density distribution in the vicinity of the selected memory cell MC in the configuration of FIG. 18.

FIGS. 9A-9C are diagrams showing a temperature distribution near a selected memory cell during writing. FIG. 9C shows a temperature distribution in the vicinity of the selected memory cell MC in the second modification example of the embodiment. FIG. 9A shows the temperature distribution in the vicinity of the selected memory cell MC in the configuration corresponding to FIG. 14. FIG. 9B shows the temperature distribution in the vicinity of the selected memory cell MC in the configuration of FIG. 18.

In the configuration corresponding to FIG. 14, the string STR does not include the resistor film 46, the outer periphery of the variable-resistance film 943 is covered with the channel semiconductor film 944, and the channel semiconductor film 944 is replaced with the channel semiconductor film 944a of FIG. 18. In the configuration corresponding to FIG. 14, at the time of writing (for example, at the time of the reset operation, as shown in FIG. 8A and FIG. 9, even though a material having a certain electric resistivity is applicable to the variable-resistance film 943 such as a phase change material (for example, GST), a bypass current flows through the variable-resistance film 943, and a selected memory cell MC portion can be selectively heated by the heat generated by the resistance of the variable-resistance film 943. However, this is limited to the material having the certain electrical resistivity of a material applicable to the variable-resistance film 943.

In the configuration of FIG. 18, the string STR includes a resistor film 946 smaller than the variable-resistance film 943. In the configuration of FIG. 18, the variable-resistance film 943 such as the phase change material has a lower electrical resistivity than a desired electrical resistivity, and instead, a resistor film 946 of a high-resistance material of about 2 nm, for example, is inserted between the variable-resistance film 943 and the channel semiconductor film 944a. In the configuration of FIG. 18, at the time of writing (for example, at the time of reset operation), as shown in FIG. 8B and FIG. 9B, the current flowing from the channel semiconductor film 944a immediately passes through the resistor film 946 and flows out the variable-resistance film 943. As a result, the temperature at which the temperature increases is lowered, and furthermore there is a temperature increase which has a wider and broader temperature increase range. When the temperature is increased by further increasing the current, the temperature of the adjacent cell increases, which may cause a variation in operating characteristics.

On the other hand, in the structure of the second modification example of the embodiment, the string STR includes the thickness of resistor film 46 is greater than the thickness of variable-resistance film 43. For example, the variable-resistance film 43 is set to 2 nm and the resistor film 46 is set to 10 nm. In the structure of the second modification example of the embodiment, as shown in FIG. 8C and FIG. 9C, the current that has entered the resistor film 46 from the channel semiconductor film 44 flows through the resistor film 46 in the Z direction since the resistor film 46 is sufficiently thick, and rather than flowing out of the variable-resistance film 43 flows out of the channel semiconductor film 44 at the Z position between the selected memory cell MC and the adjacent memory cell MC on the −Z side. As a result, in the structure of the second modification example of the embodiment, the heat is generated in the variable-resistance film 43, and since the heat is trapped on the variable-resistance film 43 side, a peak temperature of the variable-resistance film 43 becomes high. The smaller the thickness of variable-resistance film 43, the higher the equivalent resistance with respect to the resistor film 46, so that the current flows more through the resistor film 46 and the efficiency is improved.

As described above, since the string STR includes the thickness of resistor film 46 greater than the thickness of variable-resistance film 43, it becomes easier to cause the current to flow through the resistor film 46 to generate heat at the time of writing (for example, at the time of the reset operation) and to increase the temperature of the variable-resistance film 43 to a desired temperature (for example, 900 K or higher). That is, in the semiconductor storage device 1, the heat generation and the temperature rise at the time of writing to each memory cell MC can be mainly performed by the resistor film 46, and the range of the material applicable to the variable-resistance film 43 while satisfying the resistance condition for operation can be expanded.

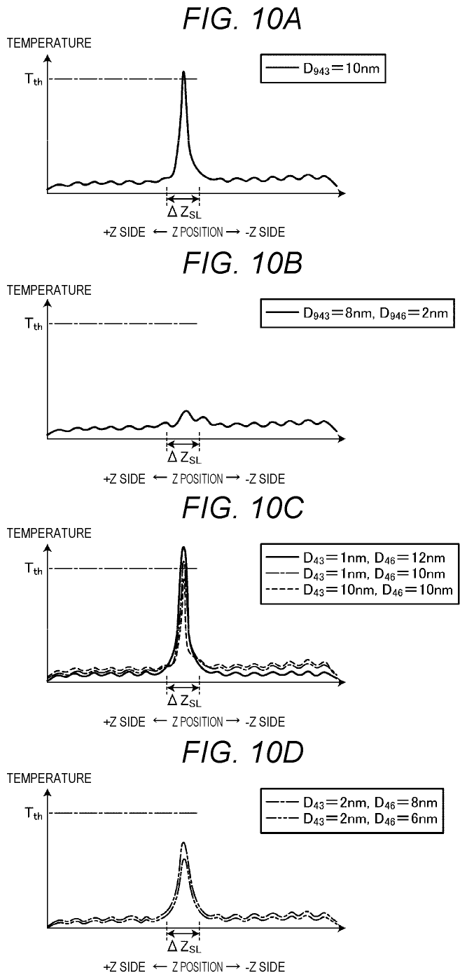

As a third modification example of the embodiment, the selected memory cell MC may operate as shown in FIG. 10C and FIG. 10D. FIG. 10 is a diagram showing a temperature distribution of the variable-resistance film at the time of writing. FIG. 10A shows a temperature distribution of the variable-resistance film at the time of writing in the configuration of FIG. 14. FIG. 10B shows the temperature distribution of the variable-resistance film at the time of writing in the configuration of FIG. 18. FIG. 10C and FIG. 10D show the temperature distribution of the variable-resistance film at the time of writing in the structure of the third modification example of the embodiment.

In FIG. 10A, the temperature distribution of the variable-resistance film 943 in a case where the film thickness of the variable-resistance film 943 is D₉₄₃=10 nm is indicated by the solid line. In FIG. 10B, the temperature distribution of the variable-resistance film 943 in a case where the film thickness of the variable-resistance film 943 is D₉₄₃=8 nm and the film thickness of the resistor film 946 is D₉₄₆=2 nm is indicated by the solid line.

In FIG. 10C, the temperature distribution of the variable-resistance film 43 in a case where the film thickness of the variable-resistance film 43 is D₉₄₃=1 nm and the film thickness of the resistor film 46 is D₄₆=12 nm is indicated by the solid line. The temperature distribution of the variable-resistance film 43 in a case where a film thickness of the variable-resistance film 43 is D₄₃=1 nm and the film thickness of the resistor film 46 is D₄₆=10 nm is indicated by the one-dot chain line. The temperature distribution of the variable-resistance film 43 in a case where a film thickness of the variable-resistance film 43 is D₄₃=2 nm and the film thickness of the resistor film 46 is D₄₆=10 nm is indicated by the dotted line.

In FIG. 10D, the temperature distribution of the variable-resistance film 43 in a case where the film thickness of the variable-resistance film 43 is D₄₃=2 nm and the film thickness of the resistor film 46 is D₄₆=8 nm is indicated by the one-dot chain line. The temperature distribution of the variable-resistance film 43 in a case where the film thickness of the variable-resistance film 43 is D₄₃=2 nm and the film thickness of the resistor film 46 is D₄₆=6 nm is indicated by the solid line.

In the configuration of FIG. 14, for example, when the variable-resistance film 943 such as the phase change material has the high resistance of 16 S/cm, as shown in FIG. 10A, the peak temperature reaches the desired temperature Tth (for example, 900 K) in the Z position range ΔZ_{SL} of the selected memory cell MC, but it is difficult to control the resistivity, and the material applicable to the variable-resistance film 943 is likely to be limited.

In the configuration of FIG. 18, the film thickness of the variable-resistance film 943 is D₉₄₃=8 nm, the film thickness of the resistor film 946 is D₉₄₆=2 nm, and the current easily flows from the resistor film 946 to the variable-resistance film 943 in the selected memory cell MC. For this reason, in the configuration of FIG. 18, as shown in FIG. 10B, in the Z position range ΔZ_{SL} of the selected memory cell MC, the temperature peak is broad and the temperature does not increase to about 500 K, and does not reach the desired temperature Tth (for example, 900 K).

In the configuration of the third modification example of the embodiment, when the film thickness of the variable-resistance film 43 become smaller to D₄₃=2 nm→1 nm and the film thickness of the resistor film 46 become greater to D₄₆=6 nm→12 nm, a current flows through the resistor film 46 in the selected memory cell MC. That is, in the configuration of the third modification example of the embodiment, the variable-resistance film 43 tends to be easily heated by the heat generation of the resistor film 46 in the order of the solid line of FIG. 10D, the one-dot chain line of FIG. 10D, the dotted line of FIG. 10C, the one-dot chain line of FIG. 10C, and the solid line of FIG. 10C, and so the variable-resistance film 43 is made thinner and the resistor film 46 is made thicker. For example, when the film thickness of the resistor film 46 is 10 nm or more, the peak temperature reaches the desired temperature Tth (for example, 900 K).

As described above, since the string STR includes the thickness of resistor film 46 greater than the thickness of variable-resistance film 43, it becomes easy to cause the current to flow through the resistor film 46 to generate heat at the time of writing (for example, at the time of the reset operation) and to increase the temperature of the variable-resistance film 43 to a desired temperature (for example, 900 K or higher). That is, in the semiconductor storage device 1, the heat generation and the temperature rise at the time of writing to each memory cell MC can be mainly performed by the resistor film 46, and the range of the material applicable to the variable-resistance film 43 while satisfying the resistance condition for operation can be expanded.

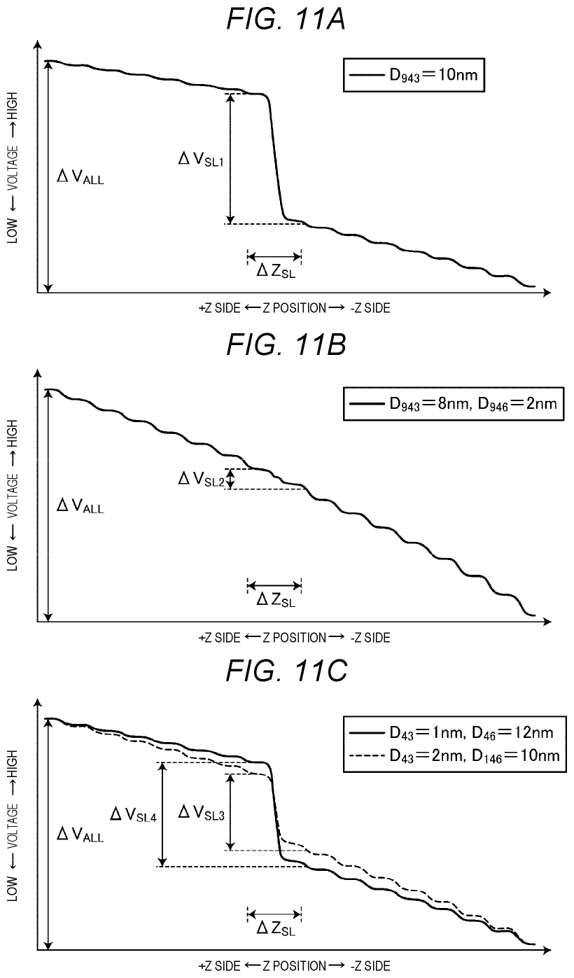

As a fourth modification example of the embodiment, the selected memory cell MC may operate as shown in FIG. 11C. FIGS. 11A-11C are diagrams showing the voltage drops in the string STR at the time of writing. FIG. 11A shows the voltage drops in the string STR at the time of writing in the configuration of FIG. 14. FIG. 11B shows the voltage drops in the string STR at the time of writing in the configuration of FIG. 18. FIG. 11C shows the voltage drops in the string STR at the time of writing in the structure of the fourth modification example of the embodiment.

In FIG. 11A, the voltage drops in the string STR in a case where the film thickness of the variable-resistance film 943 is D₉₄₃=10 nm is indicated by the solid line. In FIG. 11B, the voltage drops in the string STR in a case where the film thickness of the variable-resistance film 943 is D₉₄₃=8 nm and the film thickness of the resistor film 946 is D₉₄₆=2 nm is indicated by the solid line.

In FIG. 11C, the voltage drops in the string STR in a case where the film thickness of the variable-resistance film 43 is D₄₃=1 nm and the film thickness of the resistor film 46 is D₄₆=12 nm is indicated by the solid line. The voltage drops in the string STR in a case where the film thickness of the variable-resistance film 43 is D₄₃=2 nm and the film thickness of the resistor film 46 is D₄₆=10 nm is indicated by the dotted line.

In the configuration of FIG. 14, in a case where the voltage drop ΔV_{ALL}, (for example, 4 V) is across both ends of the string STR at the time of the writing, as shown in FIG. 11A, a relatively large voltage drop ΔV_{SL1} (for example, 2 V) is across both ends of the Z position range ΔZ_{SL} of the selected memory cell MC in the channel semiconductor film 944. In the configuration of FIG. 14, the temperature is likely to increase due to the heat generation in the variable-resistance film 943 at the time of writing, but the control of the resistivity is difficult, and the material applicable to the variable-resistance film 943 is likely to be limited.

In the configuration of FIG. 18, the film thickness of the variable-resistance film 943 is D₉₄₃=8 nm, the film thickness of the resistor film 946 is D₉₄₆=2 nm, and in the selected memory cell MC, the current easily flows through the resistor film 946 to variable-resistance film 943 and it is difficult to obtain a high equivalent resistance. For this reason, in the configuration of FIG. 18, as shown in FIG. 11B, the voltage drop ΔV_{SL2} across the ends of the Z position range ΔZ_{SL} of the selected memory cell MC in the channel semiconductor film 944 is relatively small. In the configuration of FIG. 18, the temperature is less likely to increase due to the heat generation in the variable-resistance film 943 at the time of writing, and it is difficult to achieve the set operation and the reset operation.

In the configuration of the fourth modification example of the embodiment, when the film thickness of the variable-resistance film 43 becomes small to D₄₃=2 nm→1 nm and the film thickness of the resistor film 46 becomes greater to D₄₆=10 nm→12 nm, the current easily flows in the resistor film 46 in the selected memory cell MC. That is, in the configuration of the fourth modification example of the embodiment, when the dotted line of FIG. 10C→the solid line of FIG. 10C, where the variable-resistance film 43 is made thinner and the resistor film 46 is made thicker, the voltage drop across both ends of the Z position range ΔZ_{SL} of the selected memory cell MC in the channel semiconductor film 944 is increased to ΔV_{SL3}→ΔV_{SL4}. That is, in the configuration of the fourth modification example of the embodiment, when the variable-resistance film 43 is made thinner and the resistor film 46 is made thicker, the temperature of the variable-resistance film 943 is likely to increase due to heat generation at the time of writing, and the set operation and the reset operation are easily achieved.

As described above, since the string STR includes the thickness of resistor film 46 is greater than the thickness of the variable-resistance film 43, the voltage drop across the resistor film 46 at the time of writing is increased to generate heat and the temperature can be increased, and the variable-resistance film 43 can be easily increased to the desired temperature (for example, 900 K or higher). That is, in the semiconductor storage device 1, the heat generation and the temperature rise at the time of writing to each memory cell MC can be mainly performed by the resistor film 46, and the range of the material applicable to the variable-resistance film 43 while satisfying the resistance condition for operation can be expanded.

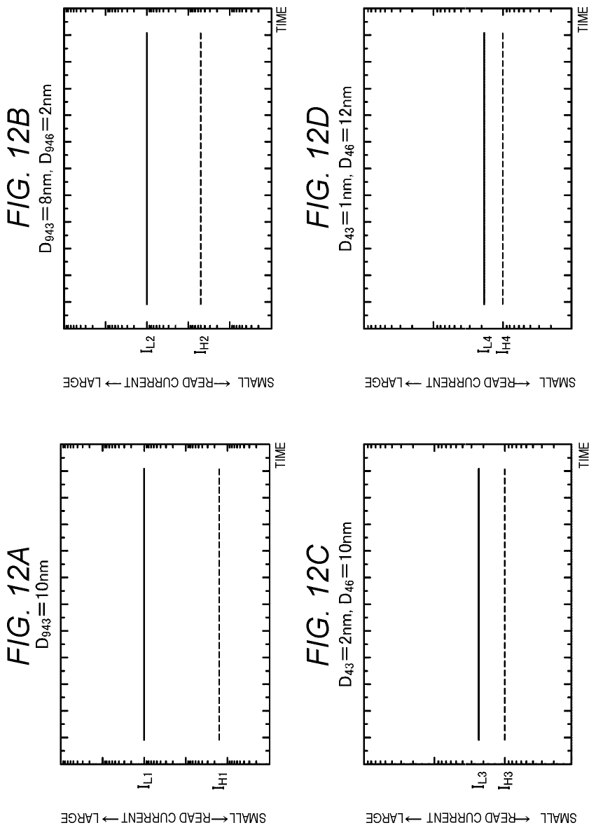

As a fifth modification example of the embodiment, the selected memory cell MC may operate as shown in FIG. 12C and FIG. 12D at the time of reading.

FIG. 12A shows the current change between the set and reset state of the memory cell MC at the time of reading in the configuration of FIG. 14. FIG. 12B shows the current change between the set and reset state of the memory cell MC at the time of reading in the configuration of FIG. 18. FIG. 12C and FIG. 12D show the current change between the set and reset state of the memory cell MC at the time of reading in the structure of the fifth modification example of the embodiment, respectively.

In FIG. 12A, the read current IL according to the resistance in the set state (low-resistance state) of the selected memory cell MC in a case where the film thickness of the variable-resistance film 943 is D₉₄₃=10 nm is indicated by the solid line, and the read current I_{H1} according to the resistance in the reset state (high-resistance state) is indicated by the dotted line. In FIG. 12B, the read current I_{L2} according to the resistance in the set state (low-resistance state) of the selected memory cell MC in a case where the film thickness of the variable-resistance film 943 is D₉₄₃=8 nm and the film thickness of the resistor film 946 is D₉₄₆=2 nm is indicated by the solid line, and the read current I_{H2} according to the resistance in the reset state (high-resistance state) is indicated by the dotted line.

In FIG. 12C, the read current I_{L3} according to the resistance in the set state (low-resistance state) of the selected memory cell MC in a case where the film thickness of the variable-resistance film 43 is D₄₃=2 nm and the film thickness of the resistor film 46 is D₄₆=10 nm is indicated by the solid line, and the read current I_{H3} according to the resistance in the reset state (high-resistance state) is indicated by the dotted line.

In FIG. 12D, the read current I_{L4} according to the resistance in the set state (low-resistance state) of the selected memory cell MC a case where the film thickness of the variable-resistance film 43 is D₄₃=1 nm and the film thickness of the resistor film 46 is D₄₆=12 nm is indicated by the solid line, and the read current I_{H4} according to the resistance in the reset state (high-resistance state) is indicated by the dotted line.

In the configuration of FIG. 14, when a predetermined voltage is applied to both ends of the string STR at the time of reading, as shown in FIG. 12A, the current ratio between the read current I_{L1} in the set state (low-resistance state) and the read current I_{H1} the reset state (high-resistance state) can be taken to be sufficiently large (for example, about 1 to 2 digits), which is not a problem.

In the configuration of FIG. 18, when the predetermined voltage is applied to both ends of the string STR at the time of reading, as shown in FIG. 12B, the current ratio between the read current I_{L2} in the set state (low-resistance state) and the read current I_{H2} in the reset state (high-resistance state) can be taken to be sufficiently large (for example, about 1 to 2 digits), which is not a problem.

In the configuration of the fifth modification example of the embodiment, each memory cell MC is equivalently a parallel resistor of the variable-resistance film 43 and the resistor film 46 (see FIG. 5C).

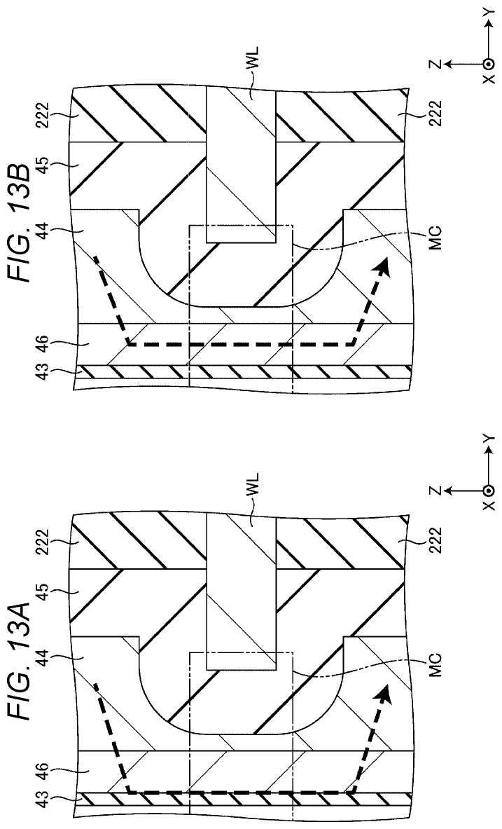

Therefore, in the configuration of the fifth modification example of the embodiment, when the predetermined voltage is applied to both ends of the string STR at the time of reading, when the variable-resistance film 43 is in the set state (low-resistance state), as shown in FIG. 13A, a part of the current flowing through the selected memory cell MC flows to the resistor film 46, and the remaining part flows from the resistor film 46 to the variable-resistance film 43. FIG. 13 is a diagram showing the current path of the memory cell MC in the set and reset state at the time of reading in the fifth modification example of the embodiment. FIG. 13 shows a position of the current path in the selected memory cell MC. When the variable-resistance film 43 is in the reset state (high-resistance state), as shown in FIG. 13B, most of the current flowing through the selected memory cell MC flows through the resistor film 46.

That is, in the configuration of the fifth modification example of the embodiment, when the predetermined voltage is applied to both ends of the string STR at the time of reading, as shown in FIG. 12C, the current ratio between the read current I_{L3} in the set state (low-resistance state) and the read current I_{H3} the reset state (high-resistance state) is relatively small (for example, about twice). Alternatively, as shown in FIG. 12D, the current ratio between the read current I_{L4} the set state (low-resistance state) and the read current I_{H4} the reset state (high-resistance state) is relatively small (for example, about twice). As long as the read current in the set state (low-resistance state) and the read current in the reset state (high-resistance state) are determined as two values even though the current ratio is relatively small, the memory can be read without any problem.

As described above, since the string STR includes the thickness of the resistor film 46 is greater than the thickness of the variable-resistance film 43, it is possible to perform two-value determination on the read current in the set state (low-resistance state) and the read current in the reset state (high-resistance state) and to perform the read operation. That is, in the semiconductor storage device 1, the read operation from each memory cell MC can be appropriately performed, and the range of the material applicable to the variable-resistance film 43 while satisfying the resistance condition for operation can be expanded.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a stacked body in which a plurality of conductive layers are stacked with an insulating layer interposed therebetween; and
a columnar structure that extends in a stacking direction in the stacked body,
wherein the columnar structure includes
a variable-resistance film that extends in the stacking direction in the stacked body,
a semiconductor film that extends in the stacking direction between the variable-resistance film and the conductive layers,
an insulating film that extends in the stacking direction between the semiconductor film and the conductive layers, and
a resistor film that extends in the stacking direction between the variable-resistance film and the semiconductor film, and
a plurality of memory cells formed at locations where the plurality of conductive layers, the variable-resistance film, and the semiconductor film intersect, wherein
in each of the plurality of memory cells, a thickness of the resistor film is greater than a thickness of the variable-resistance film.

2. The semiconductor storage device according to claim 1,
wherein the variable-resistance film is formed of a phase change material, and
the resistor film is formed of a material having an electrical conductivity of 4 S/cm or more and 40 S/cm or less.

3. The semiconductor storage device according to claim 2,
wherein the resistor film does not undergo phase change.

4. The semiconductor storage device according to claim 2,
wherein the resistor film contains a Ge atom.

5. The semiconductor storage device according to claim 4,
wherein the resistor film further contains one or more elements selected from a group consisting of P, As, Sb, and Bi as an impurity.

6. The semiconductor storage device according to claim 1,
wherein an electrical conductivity of the resistor film is 4 S/cm or more and 40 S/cm or less.

7. The semiconductor storage device according to claim 1,
a voltage applied to the conductive layer corresponding to a selected memory cell among the plurality of memory cells is lower than a voltage applied to the conductive layer corresponding to a non-selected memory cell.

8. The semiconductor storage device according to claim 1, wherein the semiconductor film of each memory cell includes
a first portion aligned with the conductive layer in a direction perpendicular to the stacking direction and
a second portion adjacent to the first portion in the stacking direction, and
a thickness of the first portion is smaller than a thickness of the second portion.

9. The semiconductor storage device according to claim 1,
wherein a thickness of the resistor film is 10 nm or more.

10. A semiconductor storage device comprising:
a stacked body in which a plurality of conductive layers and a plurality of insulating layers are stacked alternately in a first direction; and
a columnar structure that extends in the first direction through the stacked body, wherein
memory cells that are electrically connected in series are formed along the columnar structure at intersections of the columnar structure and the conductive layers, and
the columnar structure includes
an insulating film in contact with the plurality of conductive layers of the stacked body and extending in the first direction,
a semiconductor film in contact with the insulating film and extending in the first direction,
a resistor film in contact with the semiconductor film and extending in the first direction, and
a variable-resistance film having a thickness that is smaller than a thickness of the resistor film, in contact with the resistor film, and extending in the first direction.

11. The semiconductor storage device according to claim 10, wherein each of the memory cells include portions of the insulating film, the semiconductor film, the resistor film, and the variable-resistance film that are aligned with one of the conductive layers in a second direction that is perpendicular to the first direction.

12. The semiconductor storage device according to claim 10, wherein
the portion of the semiconductor film is in a low resistance state when a first voltage is applied to the conductive layer that is aligned therewith and in a high resistance state when a second voltage that is lower than the first voltage is applied to the conductive layer that is aligned therewith, and
a resistance of the resistor film is greater than a resistance of the portion of the semiconductor film in the low resistance state and less than a resistance of the portion of the semiconductor film in the high resistance state.

13. The semiconductor storage device according to claim 12, wherein during an operation performed on a selected one of the memory cells,
the first voltage is applied to the conductive layers aligned with the memory cells that are not selected and the second voltage is applied to the conductive layer aligned with the selected memory cell.

14. The semiconductor storage device according to claim 13, wherein the operation is a write operation.

15. The semiconductor storage device according to claim 11, wherein the semiconductor film has a variable thickness along the first direction.

16. The semiconductor storage device according to claim 15, wherein the semiconductor film has a first thickness at positions aligned with the conductive layers in the second direction and a second thickness that is larger than the first thickness at positions aligned in the second direction with a point that is midway between two adjacent conductive layers in the first direction.

17. The semiconductor storage device according to claim 10, wherein the variable-resistance film is formed of a phase change material, and the resistor film is formed of a formed of a material having an electrical conductivity of 4 S/cm or more and 40 S/cm or less.

18. The semiconductor storage device according to claim 17, wherein the resistor film contains a Ge atom and one or more elements selected from a group consisting of P, As, Sb, and Bi as an impurity.

19. The semiconductor storage device according to claim 10, wherein an electrical conductivity of the resistor film is 4 S/cm or more and 40 S/cm or less.

20. The semiconductor storage device according to claim 10, wherein a thickness of the resistor film is 10 nm or more.
